(19) United States
(12) Patent Application Publication
(10) Pub. No.: US 2009/0115447 A1
(43) Pub. Date: May 7, 2009

(54) Design Structure for an Integrated Circuit Having State-Saving Input-Output Circuitry and a Method of Testing Such an Integrated Circuit

(75) Inventors: Theodoros E. Anemikos, Milton, VT (US); Michael R. Ouellette, Westford, VT (US); Anthony D. Polson, Jericho Center, VT (US)

Correspondence Address: DOWNS RACHLIN MARTIN PLLC, 199 MAIN ST, PO BO 190, BURLINGTON, VT, 05402-0190, US

(73) Assignee: INTERNATIONAL BUSINESS MACHINES CORPORATION, Armonk, NY (US)

(21) Appl. No.: 11/933,646

(22) Filed: Nov. 1, 2007

(51) Int. Cl. H03K 19/003

(52) U.S. Cl. 326/9

(57) ABSTRACT

A design structure for an integrated circuit that includes input/output (I/O) state saving circuitry capable of stabilizing the I/O states during any predicted I/O disturbance event. The I/O state saving circuitry includes a plurality of transparent latches arranged between the output of a plurality of respective I/O receivers and the internal digital, analog, or mixed-signal circuitry of the integrated circuit. The transparent latches are transitioned between a pass-through mode and a state-saving mode via a common control signal. In anticipation of, for example, a predicted I/O signal disturbance generating event, the transparent latches are set to the state-saving mode. Consequently, the outputs of the transparent latches are held stable and glitchless during the disturbance event, which ensures that the internal logic of the integrated circuit does not lose state.

### FIELD OF THE DISCLOSURE

The present disclosure generally relates to the field of testing integrated circuits. In particular, the present disclosure is directed to a design structure for an integrated circuit having state-saving input/output circuitry and a method of testing such an integrated circuit.

### BACKGROUND

In testing semiconductor-based integrated circuits, in order to ensure that reliability targets are met and that high quality devices are provided to the customer, voltage stress tests are applied to these integrated circuits. The voltage stress tests are intended to stress a device under test for early failures and/or reliability failures. One example of a voltage stress test is an extended voltage screening (EVS) test. During the EVS test, one or more device power, e.g., Vdd, supplies are elevated to a certain level above their nominal operating voltages for a certain period of time and the device under test is exercised. However, in order to avoid overheating and thermal runaway, Vdd is pulsed during the EVS test, i.e., Vdd transitions between the nominal voltage and the elevated voltage. After performing the voltage stress test, the device under test is interrogated for failures. However, during the voltage transitions of the pulsed Vdd in an EVS test, voltage glitches may occur within the input/output (I/O) circuits of the integrated circuit. Consequently, there is a possibility that I/O signal levels may be misinterpreted during the Vdd transitions of the EVS test so as to cause internal logic to lose state, and, therefore, the device under test may fail the EVS test.

In order to ensure that the chip state remains stable during the EVS test, the integrated circuit's I/Os must remain stable when the device power supplies are pulsing, i.e., no voltage glitches must occur within the I/O circuits that would disturb the integrated circuit's data states. However, with advances in semiconductor technology, the semiconductor geometries are decreasing and the device power supply voltages are likewise decreasing, making this “glitchless transition” often difficult, if not impossible, to achieve.

One technique to avoid glitches in the I/O circuits is to synchronously adjust the core power supply voltages and the dedicated I/O power supply voltages during the EVS test. Additionally, an intermediate I/O power supply level that works at both the nominal supply level and at the voltage stress level may be determined. However, this intermediate voltage level is unique for each device and, thus, it is a time-consuming process to determine the intermediate I/O power supply level for all the different devices and all the different power supplies for the various I/O types.

### SUMMARY OF THE DISCLOSURE

In one embodiment, the present disclosure is directed to a design structure embodied in a machine readable medium used in a design process for an integrated circuit chip. The design structure of the integrated circuit chip includes digital circuitry; a plurality of data input circuits for loading a corresponding plurality of bits into the digital circuitry; and state-saving circuitry in electrical communication with the plurality of input circuits for inhibiting the digital circuitry from corrupting during a corrupting event of a test performed on the digital circuitry, the state saving circuitry responsive to a common state-saving control signal and comprising: a plurality of latches corresponding respectively to the plurality of data input circuits, each of the plurality of latches configured to: latch a corresponding respective one of the plurality of bits in response to the common state-saving control signal being asserted; and allow the corresponding respective one of the plurality of bits to pass therethrough when the common state-saving control signal is not asserted; and input circuitry in electrical communication with the plurality of latches for receiving the common state-saving control signal.

In another embodiment, the present disclosure is directed to a design structure embodied in a machine readable medium for performing a method of inhibiting data perturbation in at least one input circuit of digital circuitry. The design structure includes a means for providing a device having digital circuitry and digital input circuitry in communication with the digital circuitry for providing the digital circuitry with digital information; a means for transitioning the digital input circuitry from a pass-through mode to a state-saving mode prior to a perturbation generating event or a restricted data transition period so that the digital input circuitry maintains a data value in the digital input circuitry prior to the transitioning; a means for maintaining the state-saving mode of the digital input circuitry during the perturbation generating event or the restricted data transition period so that the digital input circuitry maintains the data value in the digital input circuitry; and a means for transitioning the digital input circuitry from the state-saving mode to the pass-through mode near the end of perturbation generating event or the restricted data transition period so as to pass new data into the digital circuitry.

### BRIEF DESCRIPTION OF THE DRAWINGS

For the purpose of illustrating the invention, the drawings show aspects of one or more embodiments of the invention. However, it should be understood that the present invention is not limited to the precise arrangements and instrumentalities shown in the drawings, wherein:

FIG. 1 is a schematic diagram of an integrated circuit that includes an I/O state saving circuit for holding the I/O states stable;

FIG. 2 illustrates a first example timing diagram for the I/O state saving circuit of FIG. 1;

FIG. 3 illustrates a second example timing diagram for the I/O state saving circuit of FIG. 1; and

FIG. 4 is a flow diagram of a design process used in semiconductor design, manufacturing, and/or test.

### DETAILED DESCRIPTION

The present invention is directed to a design structure for an integrated circuit having state-saving input/output circuitry and a method of testing such an integrated circuit. In one embodiment, the present disclosure is directed to an integrated circuit that includes I/O state saving circuitry capable of stabilizing the I/O states during any predicted I/O disturbance event. In one example, during an EVS test of a semiconductor, the I/O state saving circuitry of the present disclosure is able to hold the I/O states stable and glitchless during any power supply transition via a set of transparent latches so that there are no disturbances of the internal logic states of the integrated circuit. More specifically, a plurality of transparent latches are arranged between the output of a plurality of respective I/O receivers and the internal digital, analog, or mixed-signal circuitry of the integrated circuit. The transparent latches may be transitioned between a pass-through mode and a state-saving mode via a common control signal. In anticipation of, for example, a predicted I/O signal disturbance generating event, the transparent latches are set to the state-saving mode. Consequently, the outputs of the transparent latches are held stable and glitchless during the disturbance event, which ensures that the internal logic of the integrated circuit does not lose state.

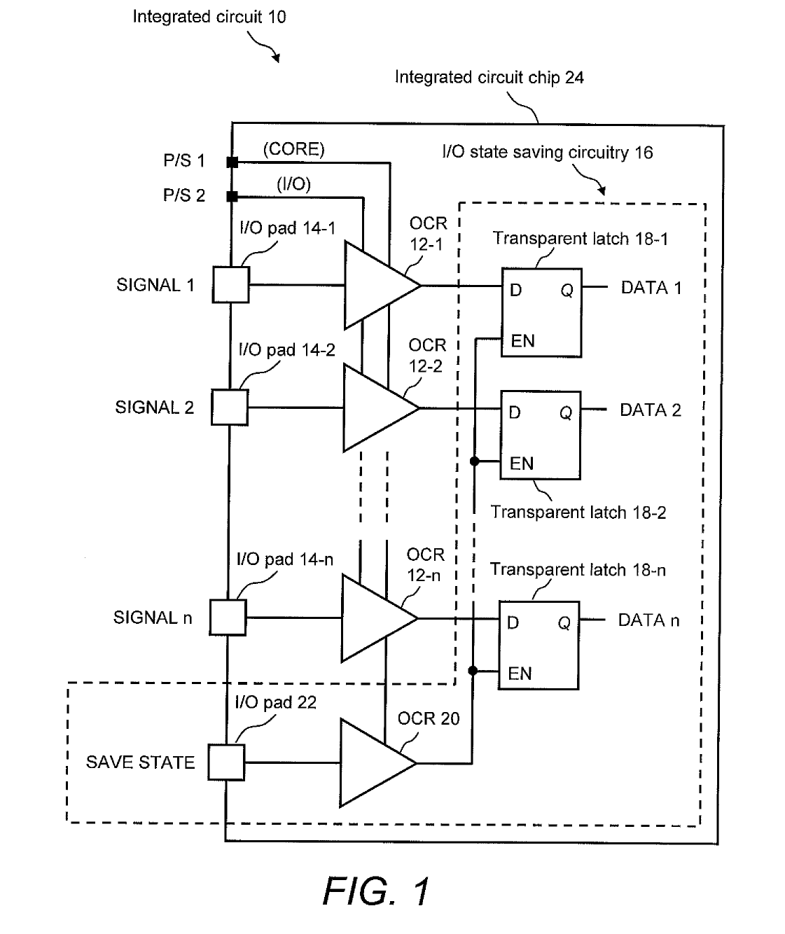

FIG. 1 illustrates an integrated circuit 10 that includes I/O state saving circuitry for holding the I/O states stable. Integrated circuit 10 may include a plurality of off-chip receivers (OCR) 12, such as, but not limited to, OCRs 12-1, 12-2, . . . 12-n. Each OCR 12 may be a standard unidirectional receiver that forms part of the corresponding I/O circuitry of integrated circuit 10. The inputs of the plurality of OCRs 12 are electrically connected to a corresponding respective plurality of I/O pads 14, for example, the inputs of OCRs 12-1, 12-2, . . . 12-n are electrically connected to I/O pads 14-1, 14-2, . . . 14-n, respectively, which are the entry points for a plurality of input signals SIGNAL 1, 2, . . . SIGNAL n, respectively. Input signals SIGNAL 1, 2 . . . SIGNAL n may be any input signals associated with a typical integrated circuit, such as, but not limited to, address, data, control, and/or clock signals. Each I/O pad 14 may be the physical signal interface for electrically connecting integrated circuit 10 to external electronics. Additionally, each OCR 12 is not limited to a unidirectional receiver. Alternatively, each OCR 12 may be a bidirectional device that is formed of both a driver and a receiver, which are connected to the same corresponding physical I/O pad 14.

Each OCR 12 may contain logic (not shown) powered by a core power supply (P/S1), which may be, for example, the main digital logic Vdd supply. Additionally, each OCR 12 may contain logic powered by a dedicated I/O power supply (P/S 2), which may be, for example, a Vdd2 or Vdd3 supply. Integrated circuit 10 is not limited to two power supplies only. Alternatively, integrated circuit 10 may be connected to three or more power supplies.

Integrated circuit 10 comprises I/O state saving circuitry 16, which may include a plurality of transparent latches 18, such as, but not limited to, transparent latches 18-1, 18-2, . . . 18-n. The outputs of OCRs 12-1, 12-2, . . . 12-n are electrically connected to data inputs (Ds) of corresponding respective transparent latches 18-1, 18-2, . . . 18-n, respectively. Additionally, each transparent latch 18 has an output (Q) that drives an output DATA signal. For example, transparent latches 18-1, 18-2, through 18-n drive a set of output signals DATA 1, 2, through n, respectively. DATA 1, 2, . . . n feed other analog, digital, or mixed-signal circuits (not shown) within integrated circuit 10. As discussed below in more detail, I/O state saving circuitry 16 also includes an additional “save-state” OCR 20 connected to a corresponding save-state I/O pad 22 for controlling the functioning of transparent latches 18 during testing via a common control signal SAVE STATE. The output of save-state OCR 20 is electrically connected to a latch-enable input (EN) of each transparent latch 18.

Each transparent latch 18 may be a standard transparent latch device that operates as a pass-through buffer when the latch-enable is not activated and latches the input data when the latch-enable is activated. For example, in I/O state saving circuitry 16, each transparent latch 18 operates as a pass-through buffer when latch-enable input EN is not activated and latches input D when latch-enable input EN is activated. The polarity of common control signal SAVE STATE may be designer defined. In the example of I/O state saving circuitry 16, a logic low at common control signal SAVE STATE latches each transparent latch 18.

Referring still to FIG. 1, the operation of integrated circuit 10 and, in particular, of I/O state saving circuitry 16 may be as follows. Input signals SIGNAL 1, 2, . . . SIGNAL n present a set of logic ones and/or zeros to I/O pads 14-1, 14-2 . . . 14-n, respectively. The logic ones and/or zeros of input signals SIGNAL 1, 2, . . . SIGNAL n are then received by corresponding respective OCRs 12-1, 12-2, . . . 12-n, which pass the logic ones and/or zeros to inputs D of corresponding respective transparent latches 18-1, 18-2, . . . 18-n. When common control signal SAVE STATE is a logic high, transparent latches 18-1, 18-2, . . . 18-n pass the logic ones and/or zeros of input signals SIGNAL 1, 2, . . . SIGNAL n, respectively, to their respective Q outputs. As a result, the logic ones and/or zeros of input signals SIGNAL 1, 2, . . . SIGNAL n are present at outputs DATA 1, DATA 2, . . . DATA n, i.e., outputs DATA 1, DATA 2 . . . DATA n follow input signals SIGNAL 1, SIGNAL 2, . . . SIGNAL n. However, when common control signal SAVE STATE is a logic low, transparent latches 18-1, 18-2, . . . 18-n are latched and outputs DATA 1, DATA 2 . . . DATA n remain stable and glitchless regardless of any changes at inputs D of transparent latches 18-1, 18-2, . . . 18-n. In doing so, the logic states of outputs DATA 1, DATA 2, . . . DATA n, which reflect the logic states of input signals SIGNAL 1, SIGNAL 2, . . . SIGNAL n, are preserved or “saved.”

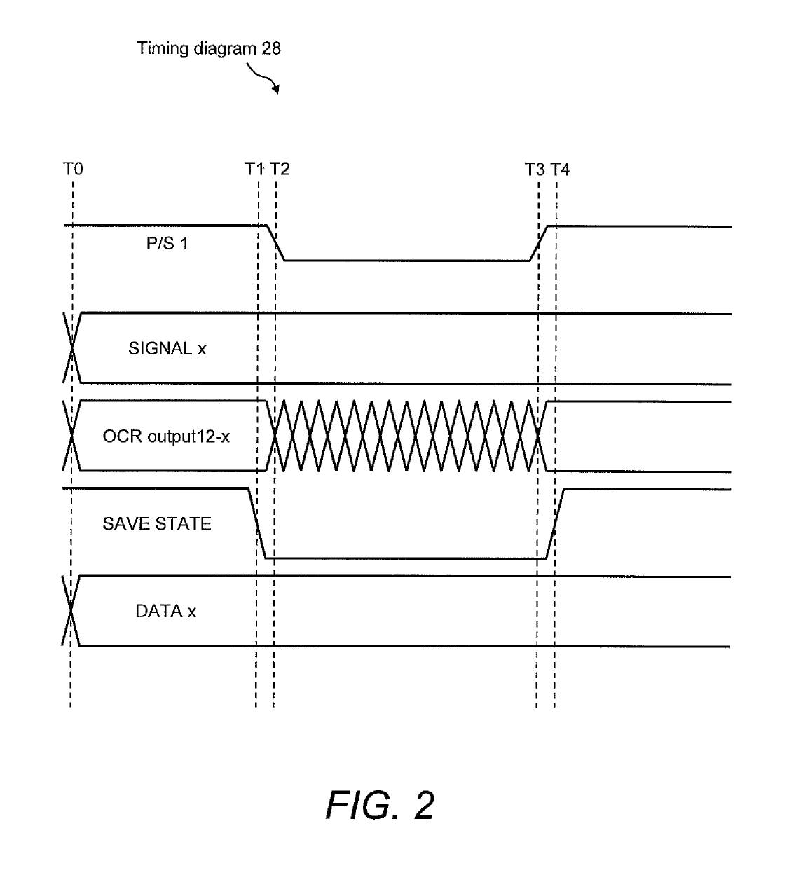

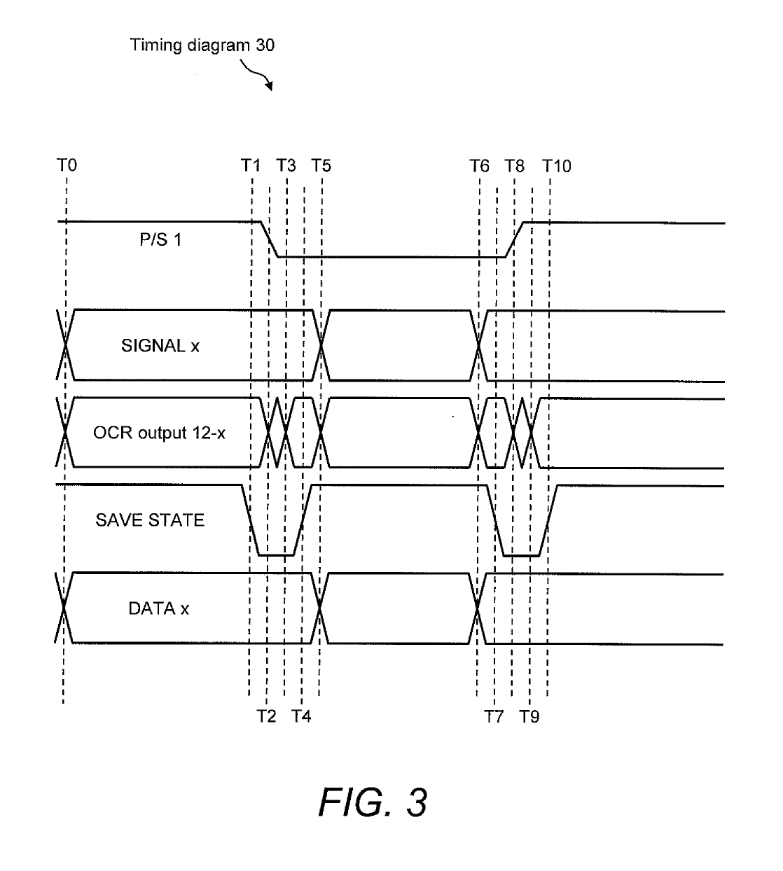

The ability of I/O state saving circuitry 16 of integrated circuit 10 to latch or save the state of input signals SIGNAL 1, SIGNAL 2, . . . SIGNAL n by use of transparent latches 18-1, 18-2, . . . 18-n, respectively, is useful to mask any predicted disturbances that may occur at the outputs of OCRs 12, which, without the presence of transparent latches 18, may cause internal logic (not shown) of integrated circuit 10 to lose state. One such scenario may exist during a voltage stress test, such as an EVS test, in the semiconductor manufacturing test operation. Further to the example, FIGS. 2 and 3 describe the operation of I/O state saving circuitry 16 of integrated circuit 10 during the EVS test.

FIG. 2 illustrates a first example timing diagram 28 of an EVS test for I/O state saving circuitry 16 of FIG. 1. In particular, timing diagram 28 shows how I/O state saving circuitry 16 is utilized to prevent disturbances that may occur at the outputs of OCRs 12, which are caused by the transitions of the pulsed Vdd (e.g., pulsed power supply P/S1), from affecting the logic levels of outputs DATA 1, DATA 2, . . . DATA n.

Timing diagram 28 shows power supply P/S1 of integrated circuit 10 at a time T0 that is set to a certain voltage stress level. At a time T2, power supply P/S1 transitions to a lower nominal voltage level. At a time T3, power supply P/S1 transitions back to the higher voltage stress level. Timing diagram 28 also shows an input signal SIGNAL x, which may be any one of input signals SIGNAL 1, SIGNAL 2, . . . SIGNAL n of integrated circuit 10 of FIG. 1. At time T0, input signal SIGNAL x is set to either a one or “0” logic level and is held at the one or “0” logic level. Timing diagram 28 also shows an OCR output 12-x, which may be the output of any one of OCRs 12-1, 12-2, . . . 12-n of integrated circuit 10 of FIG. 1. Following input signal SIGNAL x, at time T0, OCR output 12-x output is set to either a one or “0” logic level. However, at a time T2, OCR output 12-x may become unstable because of the high to low transition of power supply P/S1, which is disturbing the electronics that form OCR output 12-x; and at a time T3, OCR output 12-x becomes stable.

In order to inhibit the instability of OCR output 12-x from affecting the state of output DATA x, timing diagram 28 shows that, at time T0, common control signal SAVE STATE is set to a “1” logic level, which places transparent latches 18 in a pass-through mode of operation. At time T1, which is just prior to the predicted transition of power supply P/S1 at T2, common control signal SAVE STATE is set to a “0” logic level, which places the transparent latches in a save-state mode of operation. Common control signal SAVE STATE remains at a “0” logic level for the full duration of the disturbance at OCR output 12-x and is returned to a “1” logic level at a time T4, which is slightly after the predicted transition of power supply P/S1 at T3 and when OCR output 12-x is again stable. In other words, the timing of common control signal SAVE STATE is such that the disturbance at OCR output 12-x is completely enveloped by common control signal SAVE STATE being a “0” logic level, which holds all transparent latches 18 in a save-state mode. In doing so, output DATA x remains stable and glitchless in a manner that follows input signal SIGNAL x for the full duration of the EVS test, as shown in timing diagram 28. Because of the action of common control signal SAVE STATE and transparent latches 18, the disturbances shown at OCR output 12-x are not passed on to output DATA x, which ensures that the internal logic (not shown) of integrated circuit 10 does not lose state.

FIG. 3 illustrates a second example timing diagram 30 of an EVS test for I/O state saving circuitry 16 of integrated circuit 10 of FIG. 1. In particular, timing diagram 30 shows how I/O state saving circuitry 16 is utilized in order to prevent disturbances that may occur at the outputs of OCRs 12, which are caused by the transitions of the pulsed Vdd (e.g., pulsed power supply P/S1), from affecting the logic levels of outputs DATA 1, DATA 2, . . . DATA n.

Timing diagram 30 of FIG. 3 shows power supply P/S1 of integrated circuit 10 (FIG. 1) at a time T0 that is set to a certain voltage stress level. At a time T2, power supply P/S1 transitions to a lower nominal voltage level. At a time T8, power supply P/S1 transitions back to the higher voltage stress level. Timing diagram 30 also shows an input signal SIGNAL x, which may be any one of input signals SIGNAL 1, SIGNAL 2, . . . SIGNAL n of integrated circuit 10. At time T0, input signal SIGNAL x is set to either a one or “0” logic level and is held at the one or “0” logic level until it changes state at a time T5. Input signal SIGNAL x changes state again at a time T6.

Timing diagram 30 also shows an OCR output 12-x, which may be the output of any one of OCRs 12-1, 12-2, . . . 12-n of integrated circuit 10 of FIG. 1. Following input signal SIGNAL x, at time T0, OCR output 12-x is set to either a one or “0” logic level. Again following input signal SIGNAL x, OCR output 12-x changes state at times T5 and T6. However, OCR output 12-x has a first instability region between T2 and T3, which coincides with a transition of power supply P/S1 at T2, and OCR output 12-x has a second instability region between T8 and T9, which coincides with a transition in power supply P/S1 at T8.

In order to inhibit the instability of OCR output 12-x from affecting the state of output DATA x, timing diagram 30 shows that, at time T0, common control signal SAVE STATE is set to a “1” logic level, which places transparent latches 18 in a pass-through mode of operation. At time T1, which is just prior to the predicted transition of power supply P/S1 at T2, common control signal SAVE STATE is set to a “0” logic level, which places transparent latches 18 in a save-state mode of operation. Common control signal SAVE STATE remains at a “0” logic level for the full duration of the first disturbance at OCR output 12-x and is returned to a “1” logic level at a time T4, which is slightly after OCR output 12-x is again stable and glitchless. At time T7, which is just prior to the predicted second disturbance of OCR output 12-x, common control signal SAVE STATE is set to a “0” logic level, which places transparent latches 18 in a save-state mode of operation. Common control signal SAVE STATE remains at a “0” logic level for the full duration of the second disturbance at OCR output 12-x and is returned to a “1” logic level at a time T10, which is slightly after OCR output 12-x is again stable and glitchless.

In other words, the timing of common control signal SAVE STATE is such that the first and second disturbance at OCR output 12-x are completely enveloped by control signal SAVE STATE being a “0” logic level and, thereby, holding all transparent latches 18 in a save-state mode. In doing so, output DATA x, which may be any one of outputs DATA 1, DATA 2, . . . DATA n of I/O state saving circuitry 16, remains stable and glitchless in a manner that follows input signal SIGNAL x for the full duration of the EVS test, as shown in timing diagram 30. Because of the action of control signal SAVE STATE and transparent latches 18, the disturbances shown at OCR output 12-x are not passed on to output DATA x, which ensures that the internal logic (not shown) of integrated circuit 10 does not lose state.

Referring again to FIGS. 1, 2, and 3, a method of stabilizing the I/O states of an integrated circuit by use of I/O state saving circuitry 16 of integrated circuit 10 of FIG. 1 may include, but not limited, to the following steps:
1. transparent latches 18 of I/O state saving circuit 16 are transitioned from a pass-through mode to a state-saving mode prior to a predicted I/O signal disturbance generating event and/or prior to a restricted data transition period. In doing so, all transparent latches 18 of I/O state saving circuitry 16 maintain the value of outputs DATA 1, DATA 2, . . . DATA n present prior to the transition;
2. transparent latches 18 of I/O state saving circuitry 16 are maintained in the state-saving mode for the duration of the predicted I/O signal disturbance generating event and/or for the duration of restricted data transition period; and
3. transparent latches 18 of I/O state saving circuitry 16 are transitioned from a state-saving mode to a pass-through mode at the end of the predicted I/O signal disturbance generating event and/or at the end of the restricted data transition period. In doing so, outputs DATA 1, DATA 2, . . . DATA n of transparent latches 18-1, 18-2 . . . 18-n, respectively, may respond to input signals SIGNAL 1, SIGNAL 2, . . . SIGNAL n that pass through OCRs 12-1, 12-2, . . . 12-n, respectively, to inputs D of transparent latches 18-1, 18-2, . . . 18-n, respectively.

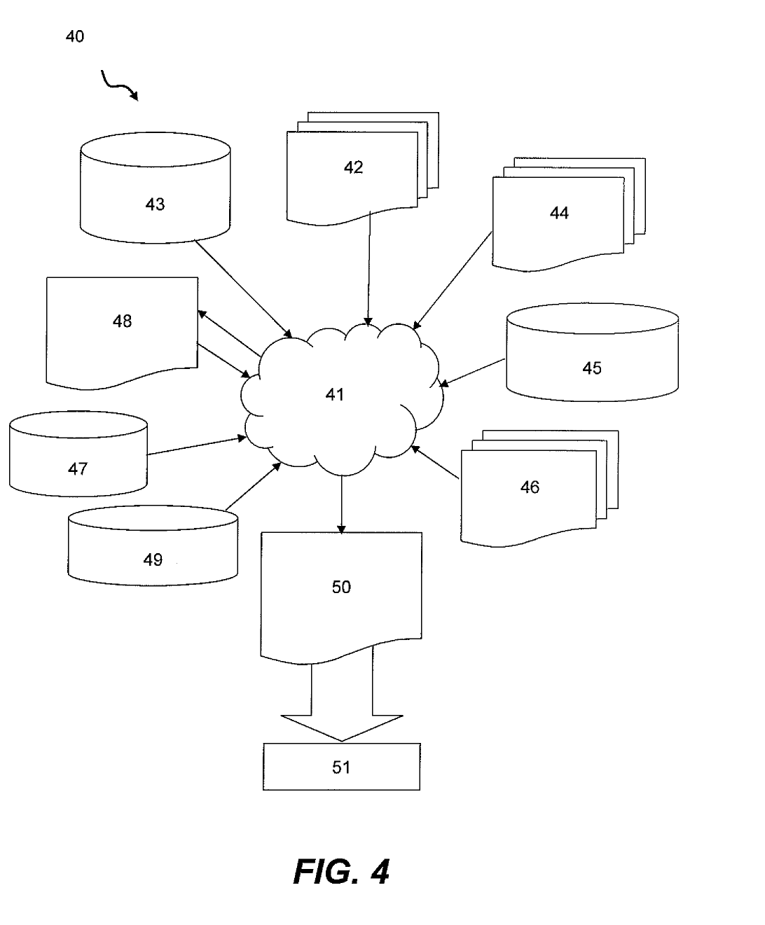

FIG. 4 shows a block diagram of an example design flow 40. Design flow 40 may vary depending on the type of IC being designed. For example, a design flow 40 for building an application specific IC (ASIC) may differ from a design flow 40 for designing a standard component. Design structure 42 is preferably an input to a design process 41 and may come from an IP provider, a core developer, or other design company or may be generated by the operator of the design flow, or from other sources. Design structure 42 comprises circuit 10 in the form of schematics or HDL, a hardware-description language (e.g., Verilog, VHDL, C, etc.). Design structure 42 may be contained on one or more machine readable medium. For example, design structure 42 may be a text file or a graphical representation of circuit 10. Design process 41 preferably synthesizes (or translates) circuit 10 into a netlist 48, where netlist 48 is, for example, a list of wires, transistors, logic gates, control circuits, I/O, models, etc. that describes the connections to other elements and circuits in an integrated circuit design and recorded on at least one of machine readable medium. This may be an iterative process in which netlist 48 is resynthesized one or more times depending on design specifications and parameters for the circuit.

Design process 41 may include using a variety of inputs; for example, inputs from library elements 43 which may house a set of commonly used elements, circuits, and devices, including models, layouts, and symbolic representations, for a given manufacturing technology (e.g., different technology nodes, 32 nm, 45 nm, 90 nm, etc.), design specifications 44, characterization data 45, verification data 46, design rules 47, and test data files 49 (which may include test patterns and other testing information). Design process 41 may further include, for example, standard circuit design processes such as timing analysis, verification, design rule checking, place and route operations, etc. One of ordinary skill in the art of integrated circuit design can appreciate the extent of possible electronic design automation tools and applications used in design process 41 without deviating from the scope and spirit of the invention. The design structure of the invention is not limited to any specific design flow.

Design process 41 preferably translates an embodiment of the invention as shown in FIG. 1, along with any additional integrated circuit design or data (if applicable), into a second design structure 50. Design structure 50 resides on a storage medium in a data format used for the exchange of layout data of integrated circuits (e.g. information stored in a GDSII (GDS2), GL1, OASIS, or any other suitable format for storing such design structures). Design structure 50 may comprise information such as, for example, test data files, design content files, manufacturing data, layout parameters, wires, levels of metal, vias, shapes, data for routing through the manufacturing line, and any other data required by a semiconductor manufacturer to produce an embodiment of the invention as shown in FIG. 1. Design structure 50 may then proceed to a stage 51 where, for example, design structure 50: proceeds to tape-out, is released to manufacturing, is released to a mask house, is sent to another design house, is sent back to the customer, etc.

An exemplary embodiment has been disclosed above and illustrated in the accompanying drawings. It will be understood by those skilled in the art that various changes, omissions and additions may be made to that which is specifically disclosed herein without departing from the spirit and scope of the present invention.

What is claimed is:

1. A design structure embodied in a machine readable medium used in a design process for an integrated circuit chip, the design structure of said integrated circuit chip comprising:
digital circuitry;
a plurality of data input circuits for loading a corresponding plurality of bits into said digital circuitry; and
state-saving circuitry in electrical communication with said plurality of input circuits for inhibiting said digital circuitry from corrupting during a corrupting event of a test performed on said digital circuitry, said state saving circuitry responsive to a common state-saving control signal and comprising:
a plurality of latches corresponding respectively to said plurality of data input circuits, each of said plurality of latches configured to:
latch a corresponding respective one of said plurality of bits in response to said common state-saving control signal being asserted; and
allow said corresponding respective one of said plurality of bits to pass therethrough when said common state-saving control signal is not asserted; and
input circuitry in electrical communication with said plurality of latches for receiving said common state-saving control signal.

2. A design structure of claim 1, wherein the design structure comprises a netlist, which describes the circuit.

3. A design structure of claim 1, wherein the design structure resides on storage medium as a data format used for the exchange of layout data of integrated circuits.

4. A design structure of claim 1, wherein the design structure includes at least one of test data files, characterization data, verification data, or design specifications.

5. A design structure embodied in a machine readable medium for performing a method of inhibiting data perturbation in at least one input circuit of digital circuitry, the design structure comprising:
a means for providing a device having digital circuitry and digital input circuitry in communication with said digital circuitry for providing said digital circuitry with digital information;
a means for transitioning said digital input circuitry from a pass-through mode to a state-saving mode prior to a perturbation generating event or a restricted data transition period so that said digital input circuitry maintains a data value in said digital input circuitry prior to said transitioning;
a means for maintaining said state-saving mode of said digital input circuitry during said perturbation generating event or said restricted data transition period so that said digital input circuitry maintains said data value in said digital input circuitry; and
a means for transitioning said digital input circuitry from said state-saving mode to said pass-through mode near the end of perturbation generating event or said restricted data transition period so as to pass new data into said digital circuitry.

6. A design structure for the method according to claim 5, wherein the steps of transitioning said digital input circuitry from said pass-through mode to said state-saving mode and maintaining said state-saving mode are achieved by asserting a save-state control signal to said digital input circuitry.

7. A design structure for the method of claim 5, wherein the step of transitioning said digital input circuitry from said pass-through mode to said state-saving mode includes providing a state-saving control signal to a state-saving latch of said digital input circuitry.

8. A design structure for the method of claim 5, wherein the step of transitioning said digital input circuitry from said pass-through mode to said state-saving mode includes providing a common state-saving control signal substantially simultaneously to a plurality of state-saving latch of said digital input circuitry.
